(19) United States
(12) Patent Application Publication
(10) Pub. No.: US 2005/0248003 A1
(43) Pub. Date: Nov. 10, 2005

(54) One dimensional nanostructures for vertical heterointegration on a silicon platform and method for making same

(76) Inventors: Leonid Tsybeskov, Rockaway, NJ (US); Andrei Sirenko, Basking Ridge, NJ (US)

Correspondence Address: KAPLAN GILMAN GIBSON & DERNIER L.L.P., 900 ROUTE 9 NORTH, WOODBRIDGE, NJ, 07095, US

(21) Appl. No.: 11/058,395

(22) Filed: Feb. 14, 2005

Related U.S. Application Data
(60) Provisional application No. 60/545,078, filed on Feb. 17, 2004.

(51) Int. Cl. H01L 29/06; H01L 21/36

(52) U.S. Cl. 257/623; 257/627; 438/763; 438/478

(57) ABSTRACT

Methods and devices are provided in which vertically integrated devices are grown in the form of semiconductor (e.g., Ge, GaAs, InGaAs, etc.) one-dimensional nanowires with typical diameter of from about 5 nm to about 50 nm and aspect ratio of about 1:10. In one embodiment a nanometer-scale diameter pillar extending from a silicon substrate is employed as a “seed” for fabricating vertical, one-dimensional hetero-structures (and/or hetero-devices) containing semiconductor materials with lattice and thermal expansion mismatches to silicon.

### CROSS REFERENCE TO RELATED APPLICATIONS

This application claims the benefit of U.S. Provisional Patent Application No. 60/545,078, entitled One Dimensional Nanostructures for Vertical Heterointegration on a Silicon Platform, by inventors Leonid Tsybeskov and Andrei Sirenko, filed Feb. 17, 2004, the entire disclosure of which is hereby incorporated by reference.

### BACKGROUND

This application relates to growth of semiconductor materials and devices and more particularly, to vertical integration of lattice and thermal expansion mismatched materials without propagating dislocations.

The integrated system-on-a-chip offers increased functionality including a combination of complementary metal oxide semiconductor (CMOS), bipolar and heterostructure-bipolar transistors, RF and THz emitters, quantum devices, optical waveguides, optical modulators, optical emitters and detectors, all integrated on one chip. Such systems require monolithic integration of devices made of different materials such as Si, Ge, GaAs, InP and the like having different lattice constants and thermal expansion coefficients.

Traditional approaches including molecular beam epitaxy (MBE) and chemical vapor deposition are used to fabricate thin film heterostructure-based devices. Due to lattice mismatch, such thin film structures contain structural interface defects known as dislocations. For example, the 4.1% lattice mismatch between GaAs and Si is a limitation in the implementation of device structures based on heteroepitaxial GaAs on silicon. This mismatch results in multiple dislocations at the heterointerface. Under typical epitaxial growth conditions, threading dislocations are formed as some of these defects thread away from the interface and into device active area such that the device cannot operate properly.

The traditional thin film approach to vertical integration of lattice mismatched materials typically consists of a relatively large area, i.e., about 100 square microns, of substrate material such as Si having deposited on substantially all of its surface a layer of material such as Ge. This approach results in large amounts of strain at the heterointerface and dislocations very near the device active area.

Another method of vertical heterointegration especially with respect to SiGe heterostructures is based on a linearly graded buffer as shown in FIG. 1, which is grown up to the desired Ge concentration at a low enough grading rate in order to reduce strain, minimize dislocation density and provide a smooth transition from Si to Ge. Germanium has a 4.2% larger lattice constant than silicon. When growing epitaxial films of germanium or the alloy Si₁₋ₓGeₓ on a silicon substrate there exists a maximum (or critical) thickness above which it costs too much energy to strain additional layers into coherence with the substrate. As a result, misfit dislocations appear which act to relieve the strain in the epitaxial film. The dislocations in the relaxed epitaxial film significantly reduce the mobility and electronic quality of the material. This prevents application of this approach in devices, such as quantum devices, where a sharp interface is desired. In addition, typical thickness of the transition (Si₁₋ₓGeₓ) layer is about 3-5 μm, and growth time by using a standard growth technique (i.e., MBE) is at least 10 hours. This technique thus requires a very long growth time and a large quantity of material.

The prior art has also focused primarily on properties of semiconductor nanowires with extremely high (greater than 1:100) aspect ratios between diameter and length. Moreover, to date, nanowires of small diameter have not been made for the purpose of establishing a connection between the nanowire itself and a substrate. Rather, efforts have been directed to the growing of nanowires and harvesting same for other applications.

Accordingly, there are needs in the art for new methods and devices for achieving vertical integration of lattice and thermal expansion mismatched materials without propagating dislocations.

### SUMMARY OF THE INVENTION

In accordance with one or more aspects of the present invention methods and devices are provided in which vertically integrated devices are grown in the form of semiconductor (e.g., Ge, GaAs, InGaAs, etc.) one-dimensional nanowires with typical diameter of from about 5 nm to about 50 nm and aspect ratio of about 1:10 (diameter:length). In one embodiment a nanometer-scale diameter silicon pillar extending from a silicon substrate is employed as a seed for fabricating vertical, one-dimensional hetero-structures (and/or hetero-devices) containing semiconductor materials with lattice and thermal expansion mismatches to silicon. These nanowires, typically comprising Ge, or III-V semiconductors such as but not limited to GaAs, or II-VI semiconductors, are grown on a silicon platform in order to fabricate vertical nanowire devices such as Gunn diodes, semiconductor lasers and the like that ordinarily could not be fabricated from silicon due to known limitations in silicon bandstructure. However, employing approaches in accordance with the present invention, these devices can be integrated into a CMOS environment. Relaxation of heterointegrated structures is maximized by employing small diameter nanowires having small nanopillar bases while localizing dislocations at the heterointerface. Any interface dislocations, if formed at all, are limited to the heterointerface and will not propagate vertically throughout the entire nanowire. The result is a device active layer that is confined within an area further away from dislocations than prior art devices as best seen in FIG. 2. In embodiments wherein more than one nanowire is grown on a substrate, the separation between the nanopillars (and hence, nanowires) prevents later dislocation propagation between nanowires.

In accordance with one aspect of the present invention, the methods and devices described thus far and/or later in this document have application in two terminal devices such as diodes and p-n junctions and three terminal devices wherein another terminal is added by providing a coating on a nanowire provided in accordance with the present invention.

In accordance with one or more further aspects of the present invention, the methods and devices described thus far and/or described later in this document, may be achieved utilizing methods well known to those having skill in the art such as molecular beam epitaxy, selective gas phase epitaxy, chemical vapor deposition (CVD) and vapor-liquid-solid (VLS) growth.

Other aspects, features and advantages of the present invention will become apparent to those skilled in the art when the description herein is taken in conjunction with the accompanying drawings.

### BRIEF DESCRIPTION OF THE DRAWINGS

For the purposes of illustration, there are forms shown in the drawings that are presently preferred, it being understood, however, that the invention is not limited to the precise arrangements and instrumentalities shown.

FIG. 1 is a schematic depiction of a prior art graded Si₁₋ₓGeₓ layer with 0<x<1 for lattice mismatched materials;

FIG. 2 is a preferred embodiment of a device in accordance with one or more aspects of the present invention;

FIG. 3 is a depiction of a comparison between prior art thin film vertical integration (left side of FIG. 3) and one-dimensional vertical heterointegration in accordance with one or more aspects of the present invention (right side of FIG. 3);

FIG. 4A is a schematic depiction of structures in accordance with one or more aspects of the present invention;

FIG. 4B is a graphical representation of Raman spectrum reflecting crystallinity and structural relaxation of structures depicted in FIG. 4A and comparison of same to germanium quantum dots grown on silicon;

FIG. 4C is a graphical representation of a photoluminescence spectrum reflecting crystallinity and structural relaxation of structures depicted in FIG. 4A;

FIG. 5 is a schematic, side-by-side depiction of semiconductor nanowire VLS growth using (a) conventional annealing methods used to prepare nanostructures, compared to (b) rapid thermal annealing used to prepare nanostructures in accordance with one or more aspects of the present invention.

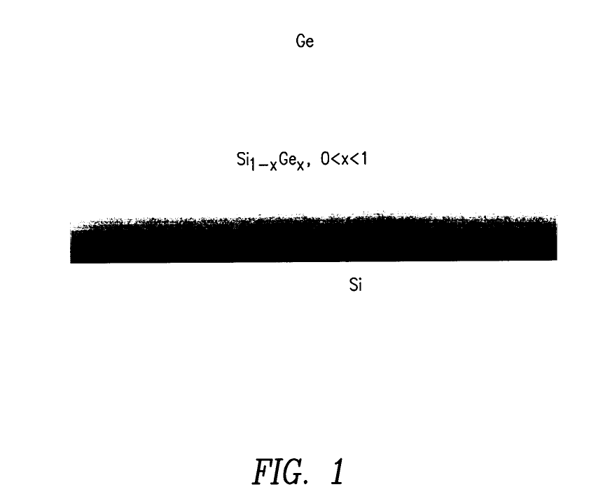

### DETAILED DESCRIPTION OF THE INVENTION

In the following description, for purposes of explanation, specific numbers, materials and configurations are set forth in order to provide a thorough understanding of the invention. It will be apparent, however, to one having ordinary skill in the art that the invention may be practiced without these specific details. In some instances, well-known features may be omitted or simplified so as not to obscure the present invention. Furthermore, reference in the specification to phrases such as “one embodiment” or “an embodiment” means that a particular feature, structure or characteristic described in connection with the embodiment is included in at least one embodiment of the invention. The appearances of phrases such as “in one embodiment” in various places in the specification are not necessarily all referring to the same embodiment.

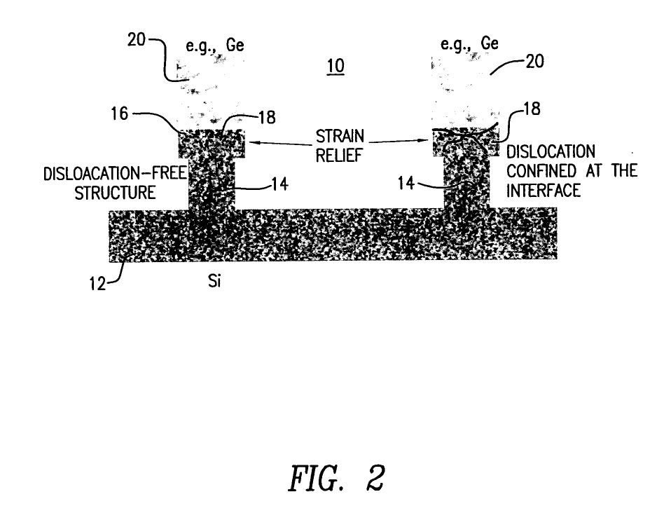

Now referring to FIG. 2 in one aspect a nanowire device 10 in accordance with the present invention comprises a Si platform 12 having disposed thereon at least one Si nanopillar 14 extending therefrom. Extending from a terminal end 16 of said Si nanopillar 14 is a length of semiconductor material 20 selected from the group consisting of Ge, a III-V semiconductor and a II-VI semiconductor. As used herein the term nanowire includes structures having a pillar or nanopillar and semiconductor material. The Si platform 12 is a suitable substrate such as but not limited to a 100, 111 substrate or the like. The Si nanopillar 14 is preferably relatively short, i.e., preferably extending from about 10 to about 20 nm in height from the platform 12, and preferably has a diameter in the range of from about 5 nm to about 50 nm. As can be seen in FIG. 2, maximum relaxation is achieved in the subject device 10 by employing a small diameter Si nanopillar 14 and localizing dislocations caused by the mismatched lattice materials to the heterointerface. By employing a thin diameter semiconductor material 20 on a Si nanopillar, strain is immediately relaxed and dislocations are confined to the heterointerface. The diameter of deposited semiconductor material is preferably in the range of from about 5 to about 50 nm. Accordingly, the device active area is able to be located further from the dislocation than is achievable in the prior art. As also can be seen, the separation between adjacent nanopillars 14 and hence, the adjacent nanowires 18, prevents dislocation propagation between nanowires 18.

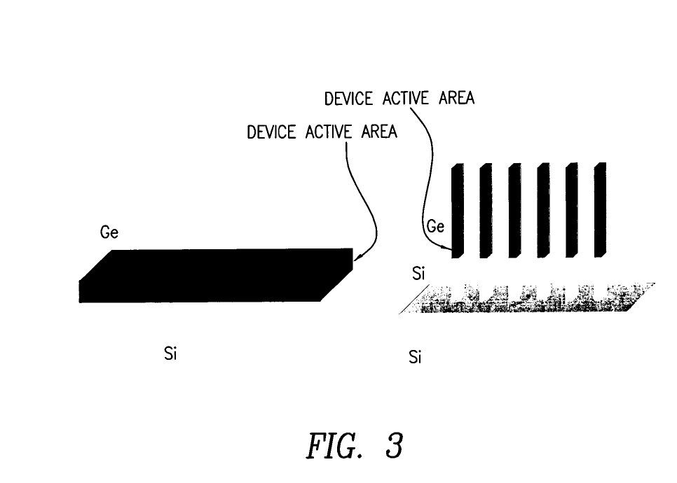

Now referring to FIG. 3 a comparison between traditional thin film and one dimensional vertical heterointegration in accordance with the present invention is depicted. As can be seen, the device active area in the prior art thin film device is much closer to the heterointerface than the device active area in the one dimensional device of the present invention. As a result, the devices in accordance with the present invention are much less likely to be influenced by dislocations than the devices in the prior art.

In one embodiment the nanowire device 10 as depicted herein is a two terminal device such as but not limited to a diode or a p-n junction. In another embodiment (not shown) the nanowire device 10 further includes a coating disposed on said semiconductor material such as but not limited to a thin (about 1 nm) silicon-rich SiGe coating to prevent oxidation according to techniques well known to those having skill in the art. A coating such as but not limited to Al, Ti, or other metal may be applied in accordance with techniques known by those skilled in the art for metallizing CMOS may be included with or without an oxidation-preventing coating to provide a side gate creating a three terminal device such as but not limited to a vertical transistor.

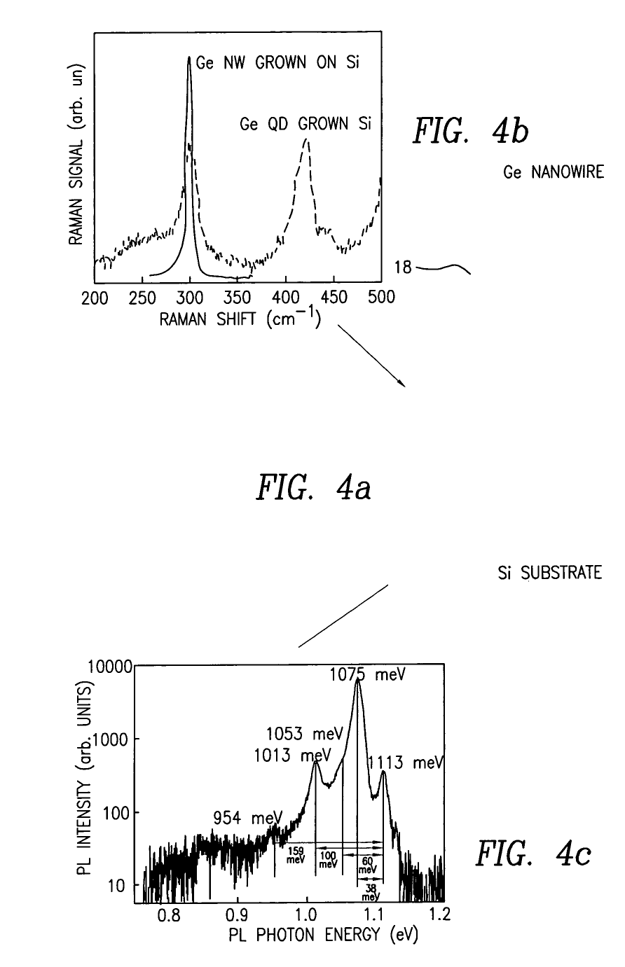

Now referring to FIGS. 4A-C, Raman and photoluminescence (PL) spectra show high crystallinity and complete structural relaxation of germanium nanowires. FIG. 4A depicts germanium nanowires on a silicon substrate in accordance with one aspect of the present invention. The diameter of the nanowires 18 in this embodiment is 20 nm and the height of the nanowires is about 200-300 nm. In FIG. 4B the Raman spectrum of partially relaxed germanium quantum dots grown on a silicon substrate (with an additional Raman peak at ˜420 cm⁻¹ related to SiGe intermixing and a broad Raman feature at 250 cm⁻¹ associated with disordered germanium) is shown for comparison. The observed fine structure in the PL spectrum in FIG. 4C is identified and associated with the energies of specific silicon and germanium phonons. These data show that a small nanowire diameter allows efficient lateral relaxation of nanowire atoms, thereby providing the freedom to combine materials and substrates with very different lattice constants (e.g., Ge and Si, or GaAs and Si, etc.), and no dislocations or other structural defects at the nanowire foundation.

The basic mechanism governing nanowire growth using a vapor-liquid-solid (VLS) process is the unidirectional growth of the crystal using selectively placed liquid precursor such as gold. The unidirectional growth of the VLS nanowire results from the difference of the sticking coefficients of the impinging vapor phase semiconductor atoms on liquid and on solid substrate surfaces. Being an ideal rough surface with a high sticking coefficient, the liquid precursor surface captures substantially all the impinging atoms, while the solid substrate surfaces (without precursor) reject almost all of these atoms because the sticking coefficients are orders of magnitude smaller. Thus, axial growth of the nanowire crystal fed by the liquid has growth rate orders of magnitude greater compared to its lateral growth rate. However, thermal diffusion of a molten precursor such as gold can result in an unwanted lateral expansion and merge of a growth seed cluster. In such instances lateral propagation of dislocations is likely.

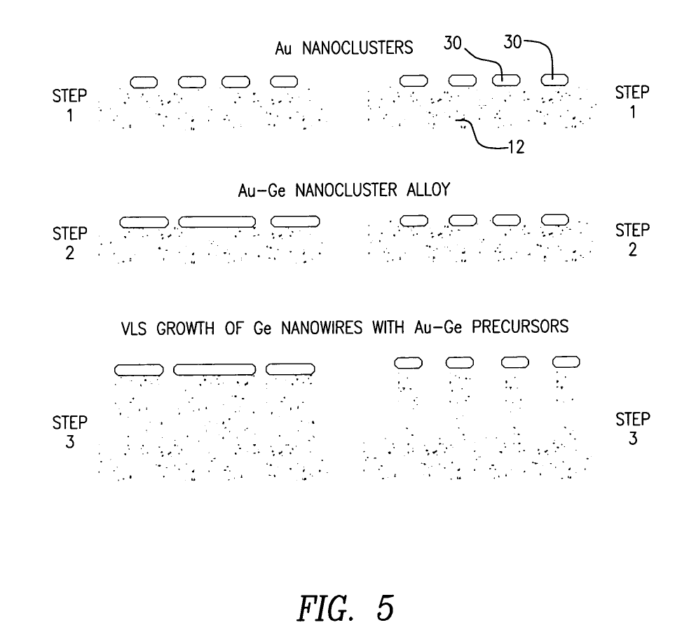

Now referring to FIG. 5, in a preferred embodiment the invention comprises a method of performing seed formation, that is, substrate-precursor alloying, by using rapid thermal annealing, such as 10-20 seconds at 650° C. for a Ge—Au system, instead of the steady furnace annealing at 650° C. for 15-30 minutes as is used in the prior art. The present inventors have surprisingly found that such a short annealing time is enough to form nanoscale alloy droplets such as Ge—Au with little or no lateral diffusion of gold at the substrate surface. The steps 1-3 in column (a) of FIG. 5 show the drawbacks of conventional annealing processes, where the nanocluster alloy seeds diffuse laterally (best seen in steps 2 and 3) and form larger diameter vertical structures. Steps 1-3 in column (b) illustrate the lack of diffusion of the alloy seeds that occurs in a rapid annealing process in accordance with the teachings of the present invention.

Preferably, precursor seeds 30 are disposed on a platform 12 in “spots” about 5-10 nm in diameter. Suitable precursors include but are not limited to Au, Ga and Ta and other precursors known to those having skill in the art.

In another embodiment, the present invention comprises a method of making a vertically heterointegrated semiconductor device having lattice mismatched materials without propagating dislocations comprising the steps of providing a silicon substrate, disposing a precursor alloy on said substrate, depositing on said substrate a silicon pillar having a diameter of from about 5 to about 50 nm to a height of about 10 to about 20 nm by a method such as conventional molecular beam epitaxy, selective gas phase epitaxy, chemical vapor deposition (CVD) or vapor-liquid-solid (VLS) growth, and depositing on an end of said pillar a semiconductor material selected from the group consisting of Ge, III-V semiconductors and II-VI semiconductors. In a most preferred embodiment the foregoing method is preceded by a substrate-precursor alloying step employing rapid thermal annealing, such as 10-20 seconds at 650° C. for a Ge—Au system.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A vertically heterointegrated device comprising lattice mismatched materials comprising a silicon platform, at least one silicon nanopillar extending therefrom, said nanopillar having a free end and a semiconductor material extending from said nanopillar.

2. A device in accordance with claim 1 said platform selected from the group consisting of 100 and 111 substrates.

3. A device in accordance with claim 1 said nanopillars having a diameter of about 5 nm to about 50 nm.

4. A device in accordance with claim 1 said nanopillars having a height as measured from said platform to said free end of about 10 nm to about 20 nm.

5. A device in accordance with claim 1 said semiconductor material selected from the group consisting of Ge, III-V semiconductors and II-VI semiconductors.

6. A device in accordance with claim 1 comprising a two terminal device

7. A device in accordance with claim 1 comprising a Gunn diode.

8. A device in accordance with claim 1 comprising a p-n junction.

9. A device in accordance with claim 1 further comprising at least one coating disposed at least on said semiconductor material.

10. A device in accordance with claim 9 comprising a three terminal device.

11. A method of vertical heterointegration of lattice mismatched materials comprising the steps of:
providing a silicon platform;
disposing a precursor alloy on said platform;
depositing on said platform at least one silicon pillar having a diameter of about 5 nm to about 50 nm; and
depositing on an end of said pillar a second semiconductor material selected from the group consisting of Ge, III-V semiconductors and II-VI semiconductors.

12. The method according to claim 11, said pillar deposited on said platform to a height of about 10 nm to about 20 nm.

13. The method according to claim 11, said depositing steps employing conventional molecular beam epitaxy, selective gas phase epitaxy, chemical vapor deposition (CVD) or vapor-liquid-solid (VLS) growth.

14. The method according to claim 11 further comprising an initial substrate-precursor alloying step employing rapid thermal annealing.

15. The method according to claim 14 said rapid thermal annealing comprising heating said precursor for from about 10 to about 20 seconds at about 650° C.

16. A device comprising at least one one-dimensional vertical nanopillar extending from a silicon platform, said nanopillar having a free end adapted to receive a semiconductor material.

17. A device according to claim 16, said nanopillar consisting of silicon.

18. A device according to claim 16, said semiconductor material selected from the group consisting of Ge, III-V semiconductors and II-VI semiconductors.
